(19) United States
(12) Patent Application Publication
(10) Pub. No.: US 2014/0197508 A1
(43) Pub. Date: Jul. 17, 2014

(54) IMAGE SENSOR AND METHOD FOR FABRICATING THE SAME

(71) Applicant: UNITED MICROELECTRONICS CORPORATION, HSINCHU (TW)

(72) Inventors: Yi-Hsu CHEN, Taichung City (TW); Yuh-Turng LIU, Hsinchu City (TW); Yu-Ming WANG, Hsinchu County (TW)

(73) Assignee: UNITED MICROELECTRONICS CORPORATION, HSINCHU (TW)

(21) Appl. No.: 13/744,341

(22) Filed: Jan. 17, 2013

(51) Int. Cl. H01L 27/146

(52) U.S. Cl. CPC H01L 27/14621; H01L 27/14685
USPC 257/432; 438/70

(57) ABSTRACT

An image sensor comprises a substrate, a plurality of image sensing elements and a first inorganic optical layer, wherein the substrate has an active region; the image sensing elements are disposed in the active region; and the first inorganic optical layer covers the image sensing elements and has at least two adjacent edges for forming an angle greater than 90 degrees (90°).

### FIELD OF THE INVENTION

The present invention relates to a semiconductor device and the method for fabricating the same, more particularly to an image sensor and the method for fabricating the same.

### BACKGROUND OF THE INVENTION

An image sensor, such as a metal-oxide-semiconductor (MOS) image sensor, is a photoelectric device used to convert optical images into electrical signals and has been widely applied in various consumer products, for example, digital cameras, camcorders, personal communication systems (PCSs), game equipment, requiring for improved image resolution.

An image sensor typically has a stacked structure comprising a substrate, a plurality of photo-sensing devices, an interconnect structure and a plurality of optical films. The plurality of photo-sensing devices include a plurality of photodiodes and transistors formed in the substrate. The interconnect structure include inter-metal dielectric (IMD) layer, metal lines and metal pads formed on the substrate. The optical films, such as color filter, micro-lenses and black matrix, are formed on the interconnect structure. In some cases, the stacked structure may further comprise a plurality of dielectric layers combined to serve as a passivation layer covered on the optical films.

However, the dielectric layers and the optical films are easily cracked due to thermal and mechanical stress. Unfortunately, the process for fabricating an image sensor or the subsequent downstream processes for further integrating with other devices comprise of repeated thermal treatment testing or packaging steps which may incur thermal stress and mechanical stress. Therefore, to prevent the dielectric layers or the optical films of the image sensor from being cracked in order to increase the yield of the image sensor is still a challenge to the industry.

### SUMMARY OF THE INVENTION

In accordance with one aspect, the present invention provides an image sensor comprising a substrate, a plurality of image sensing elements and a first inorganic optical layer, wherein the substrate has an active region; the image sensing elements are disposed in the active region; and the first inorganic optical layer covers the image sensing elements and comprises at least two adjacent edges for forming an angle greater than 90 degrees (90°).

In one embodiment of the present invention, the first inorganic optical layer allows light with a wavelength substantially ranging from 780 nm to 390 nm passing there through.

In one embodiment of the present invention, the first inorganic optical layer has a thickness substantially ranging from 3 μm to 6 μm.

In one embodiment of the present invention, the image sensor further comprises a second inorganic optical layer covering the image sensing elements and having at least two adjacent edges for forming an angle greater than 90 degrees (90°).

In one embodiment of the present invention, the second inorganic optical layer allows light with a wavelength substantially greater than 850 nm passing therethrough.

In one embodiment of the present invention, the first inorganic optical layer and the second inorganic optical layer are partially overlapped.

In one embodiment of the present invention, the first inorganic optical layer is disposed adjacent to the second inorganic optical layer. In further embodiment of the present invention, the first inorganic optical layer is disposed of separate from the second inorganic optical layer.

In one embodiment of the present invention, the image sensor further comprises a color filter layer and a plurality of micro-lenses, wherein the color filter layer is disposed between the image sensing elements and the first inorganic optical film; and the micro-lenses is disposed between the color filter layer and the first inorganic optical film.

In one embodiment of the present invention, the image sensor further comprises a planarizing layer disposed between the color filter layer and the first inorganic optical film or disposed over the first inorganic optical film.

In one embodiment of the present invention, the first inorganic optical layer has at least one rounded corner.

In one embodiment of the present invention, the image sensor further comprises a color filter layer, a planarizing layer and a plurality of micro-lenses, wherein the color filter layer is disposed over the first inorganic optical film; the planarizing layer is disposed over the color filter layer; and the plurality of micro-lenses is disposed over the planarizing layer.

In accordance with another aspect, the present invention provides a method for fabricating an image sensor, wherein the method comprises steps as follows: Firstly, a plurality of image sensing elements are formed in an active region of a substrate. Subsequently, a first inorganic optical layer is formed to cover the image sensing elements, wherein the first inorganic optical layer comprises at least two adjacent edges for forming an angle greater than 90 degrees (90°).

In one embodiment of the present invention, the method further comprises steps of forming a second inorganic optical layer covering the image sensing elements, wherein the second inorganic optical layer comprises at least two adjacent edges for forming an angle greater than 90 degrees (90°).

In one embodiment of the present invention, the first inorganic optical layer and the second inorganic optical layer are partially overlapped.

In one embodiment of the present invention, the second inorganic optical layer is formed adjacent to the first inorganic optical layer.

In one embodiment of the present invention, the first inorganic optical layer is deposited on the image sensing elements by an evaporation process.

In one embodiment of the present invention, the evaporation process has an operating temperature substantially less than a heat deformation temperature of the color filter layer.

In one embodiment of the present invention, the evaporation process has an operating temperature substantially ranging form 50° C. to 250° C.

In one embodiment of the present invention, before the step of forming the first inorganic optical film, the method further comprises steps of forming a color filter layer on the image sensing elements and forming a plurality of micro-lenses disposed on the color filter layer.

In one embodiment of the present invention, further comprising steps of forming a planarizing layer between the color filter layer and the first inorganic optical film or over the first inorganic optical film.

In one embodiment of the present invention, after the step of forming the first inorganic optical film, the method further comprises steps of forming a color filter layer on the first inorganic optical film; forming a planarizing layer over the color filter layer; and forming a plurality of micro-lenses disposed on the planarizing layer.

In accordance with the aforementioned embodiments of the present invention, an image sensor having a novel inorganic optical layer is provided, wherein the inorganic optical layer covers a plurality of image sensing elements of the image sensor and comprises at least two adjacent edges for forming an angle greater than 90 degrees (90°). Since the obtuse angle or rounded corners formed by the two adjacent edges of the inorganic optical layer may help to release the tensile or compression stress imposed on the image sensor, thus thermal stress and mechanical stress and adverse effects of the like resulted from the process for fabrication the image sensor or the subsequent downstream processes for further integrating with other devices can be reduced. As a result, yield of the image sensor can be significantly improved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A-1E are cross-sectional views of the processing structures for fabricating an image sensor in accordance with one embodiment of the present invention;

FIG. 1 illustrates a plan view of the image sensor in accordance with FIG. 1E;

FIG. 2 illustrates a plan view of an image sensor in accordance with one embodiment of the present invention;

FIG. 3 is a plan view illustrating an image sensor, in accordance with one embodiment of the present invention;

FIG. 4 is a plan view illustrating an image sensor, in accordance with one embodiment of the present invention;

FIG. 5 is a cross-sectional view illustrating an image sensor, in accordance with another embodiment of the present invention;

FIG. 6 is a cross-sectional view illustrating an image sensor, in accordance with yet another embodiment of the present invention; and

FIG. 7 is a cross-sectional view illustrating an image sensor, in accordance with further another embodiment of the present invention.

### DETAILED DESCRIPTION OF PREFERRED EMBODIMENTS

An image sensor and the method for fabricating the same are provided by the present invention. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

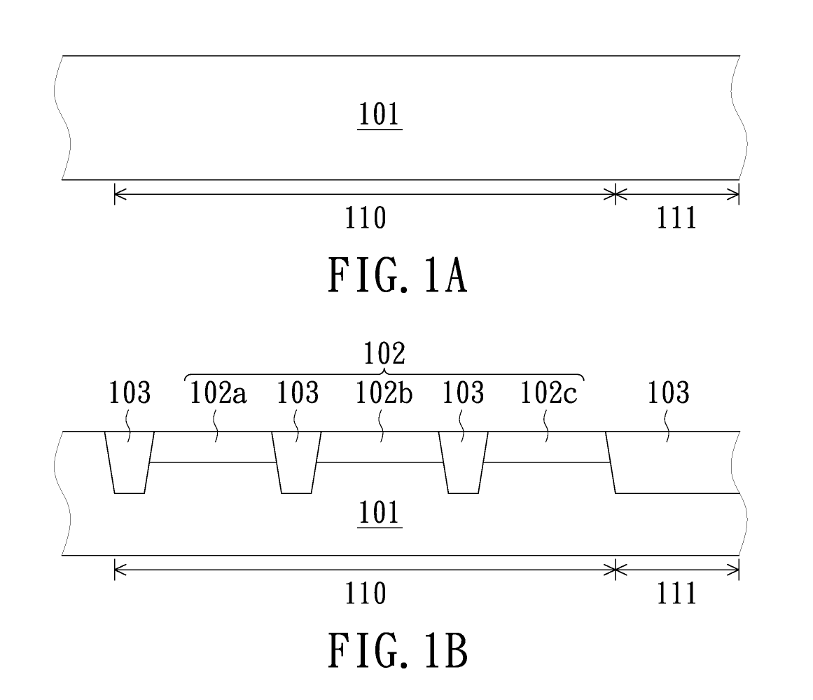

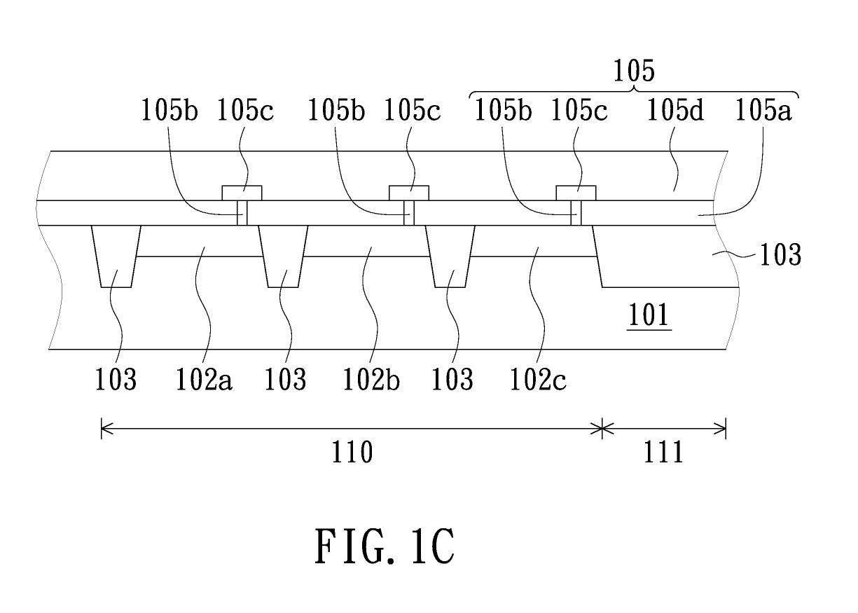

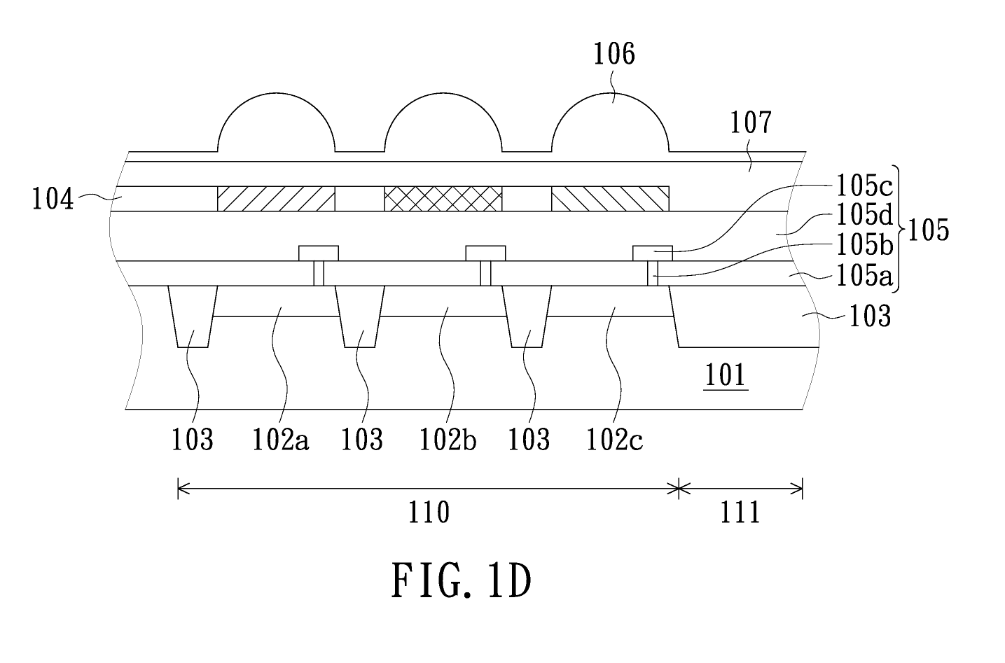

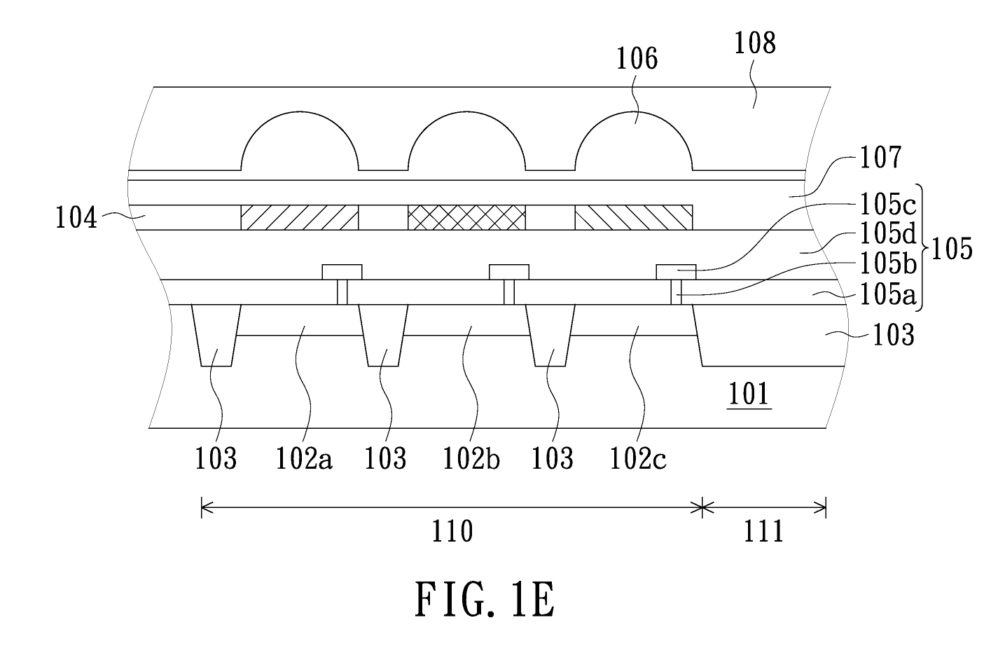

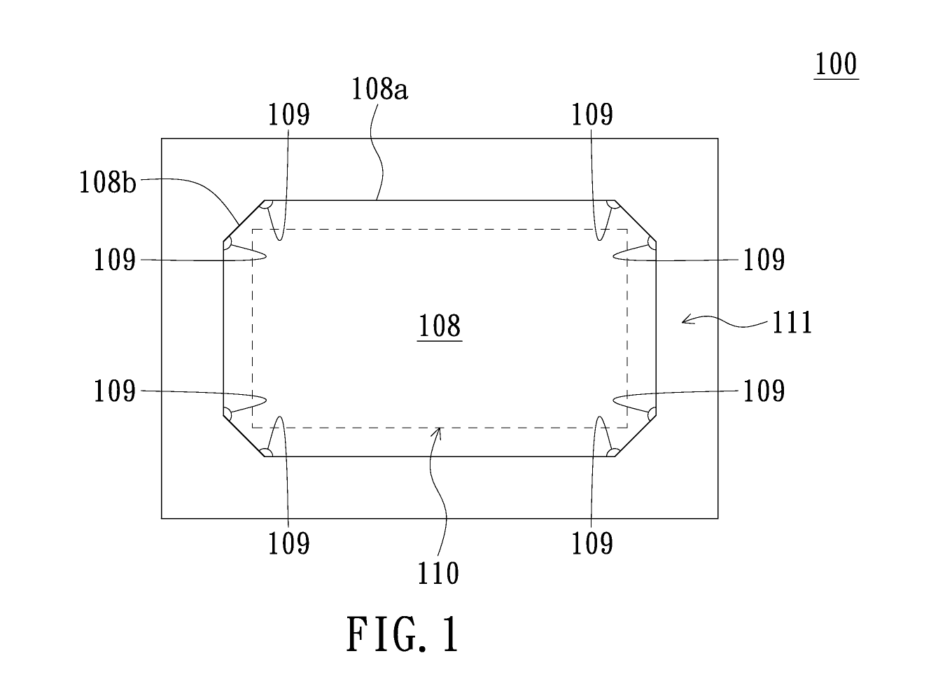

FIGS. 1A-1E are cross-sectional views of the processing structures for fabricating an image sensor 100 in accordance with one embodiment of the present invention, wherein the method for fabricating the image sensor 100 comprises steps as follows:

A substrate 101 having an active region 110 and a peripheral region 111 is firstly provided (see FIG. 1A). In some embodiments of the present invention, the substrate 101 is a glass substrate, a silicon substrate or a silicon-on-insulator (SOI) wafer.

A front-side process is then performed on the active region 110 of the substrate 101 to form a plurality of image sensing elements 102a, 102b and 102c and a plurality of isolation structures 103 on the substrate 101 (see FIG. 1B), wherein the image sensing elements 102a, 102b and 102c are divided by the isolation structures 103 (i.e. a plurality of shallow trench isolations (STIs) formed in the substrate 101), so as to be arranged as an image sensing element matrix 102. Each of the image sensing elements 102a, 102b and 102c comprises a photodiode and at least one transistor (not shown).

An interconnect structure 105 is subsequently formed on the substrate 101 and electrically connects to the image sensing element matrix 102 (see FIG. 1C). The process for forming the interconnect structure 105 comprises the following steps: A dielectric layer 105a is firstly formed on the substrate 101 to cover the image sensing element matrix 102. Next, at least one conductive via 105b is formed in the dielectric layer 105a. Subsequently, a patterned metal layer 105c is then formed on the dielectric layer 105a and in contact with the conductive via 105b.

After the patterned metal layer 105c is formed, another dielectric layer 105d is then formed to cover the patterned metal layer 105c. In some embodiments of the present invention, the aforementioned step for forming the interconnect structure 105 may be repeated for several times, so as to form a staged stacked structure comprises plural dielectric layers, conductive vias and patterned metal layers.

A color filter layer 104 and a plurality of micro-lenses 106 are then formed on the interconnect structure 105 in sequence (see FIG. 1D). In some embodiments of the present invention, the color filtering layer 104 comprises a plurality of optical filtering elements with an individual color. However, in some other embodiments of the present invention, the color filter layer 104 alternately includes a plurality of color filtering elements with various colors including red, green, blue, cyan, magenta or yellow.

In some embodiments, prior to forming the micro-lenses 106, a planarizing layer 107 may be formed on the color filter layer 104. In the present embodiment, the planarizing layer 107 and the micro-lenses 106 both are of acrylate material.

Afterward, an inorganic optical layer 108 is formed on the micro-lenses 106, while the image sensor 100 is being formed (see FIG. 1E). In some embodiments of the present invention, the inorganic optical layer 108 is a dielectric layer formed by a vapor deposition process or thermal evaporation process. In the present embodiment, the inorganic optical layer 108 is made of a dielectric material comprising of metal oxide, such as titanium oxide (TiO₂), compositions of Ti/Si/O or the like.

However, it should be noted that, in other embodiments of the present invention, the sequence of steps for forming the inorganic optical layer, the color filter layer 104, the micro-lenses 106, and the planarizing layer 107 may be varied.

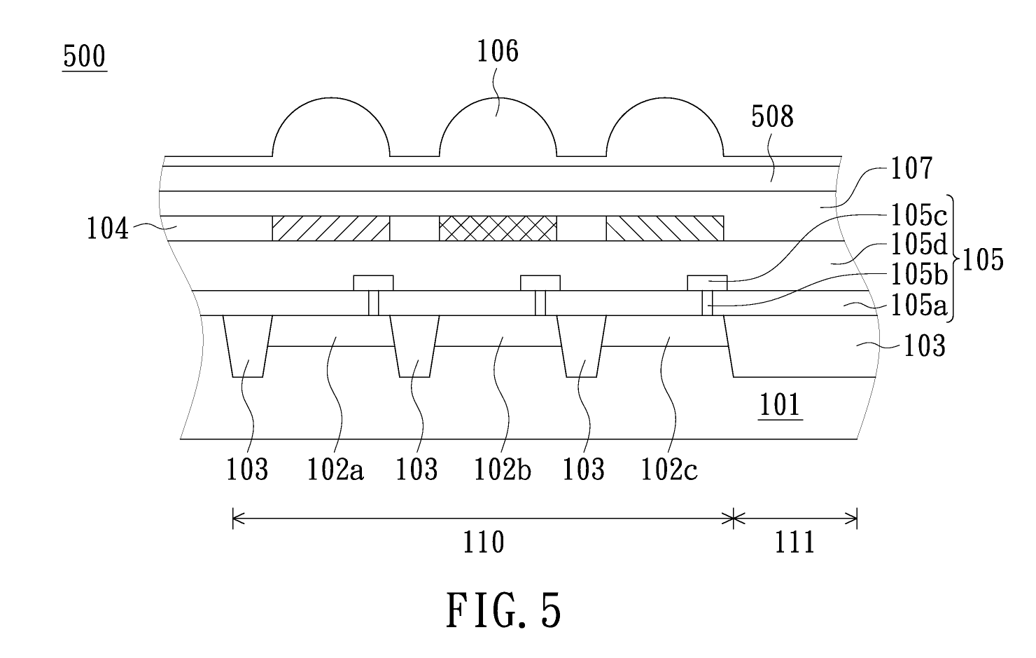

For example, the inorganic optical layer can also be formed between the color filter layer 104 and the plurality of micro-lenses 106. FIG. 5 illustrates a cross-sectional view of an image sensor 500, in accordance with another embodiment of the present invention. The image sensor 500 is structurally similar to that of the image sensor 100 depicted in FIG. 1E, except that, in the present embodiment, the inorganic optical layer 508 is formed on the planarizing layer 107 prior to the forming of the micro-lenses 106 (wherein similar reference numbers are used in FIG. 5 to indicate similar elements as the embodiment depicted in FIG. 1E).

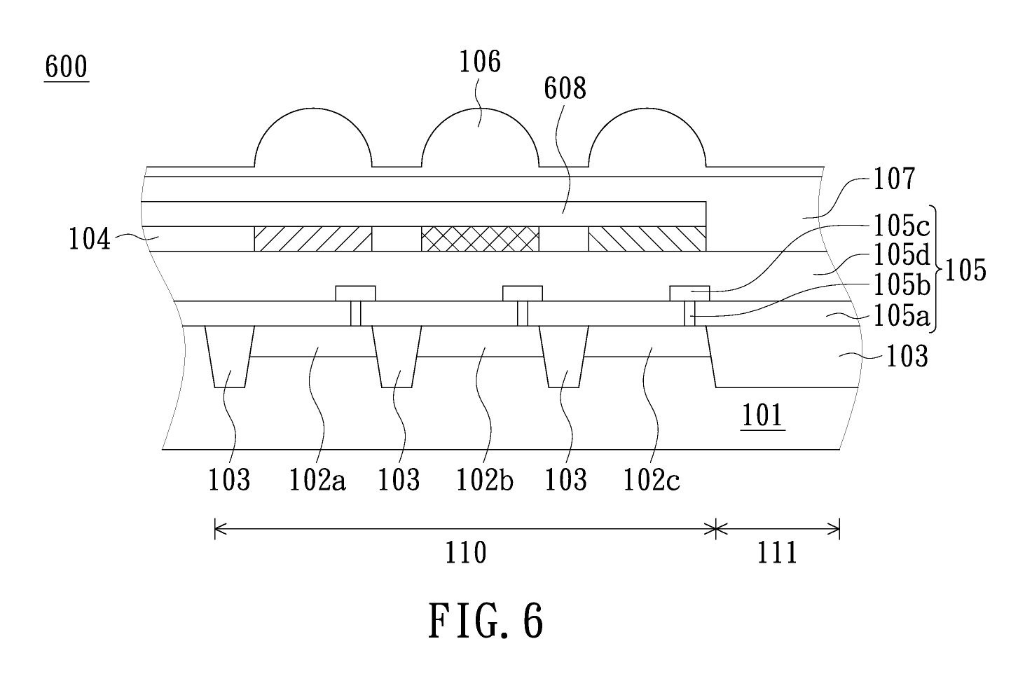

FIG. 6 illustrates a cross-sectional view of an image sensor 600 in accordance with yet another embodiment. Similar to the image sensor 500, the inorganic optical layer 608 of the image sensor 600 is also disposed on the color filter layer 104. However, the steps for forming the image sensor 600 are different from that of forming the image sensor 500, wherein the planarizing layer 107 is formed over the color filter 104 before the forming of the inorganic optical layer 608.

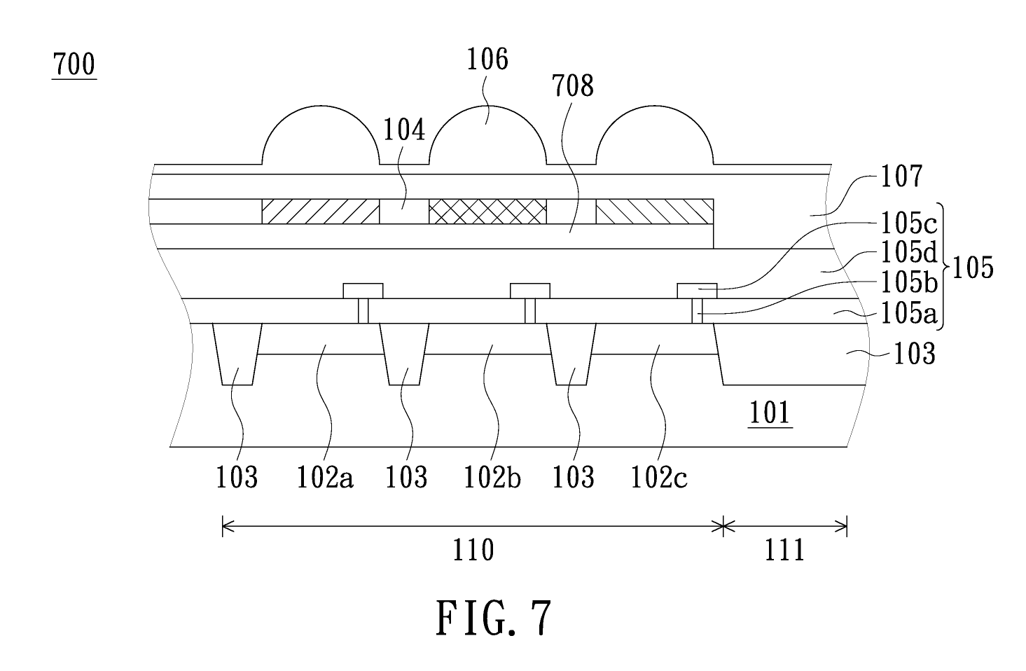

FIG. 7 illustrates a cross-sectional view of an image sensor 700 in accordance with further another embodiment, wherein the color filter layer 104 is disposed between the micro-lenses 106 and the inorganic optical layer 708. In the present embodiment, the inorganic optical layer 708 is firstly formed over the image sensing element matrix 102; the color filter layer 104 is then formed over the inorganic optical layer 708; the planarizing layer 107 is next formed over the color filter layer 104; and the plurality of micro-lenses 106 are subsequently formed over the planarizing layer 107.

In some embodiments of the present invention, the inorganic optical layer 108 or the inorganic optical layer 508 may serve as a passivation layer used to protect the image sensor 100, 500 from being damaged by abrasion or other mechanical impacts.

In some other embodiments of the present invention, the inorganic optical layer 108 serves as an optical film to allow some of the incident-light having a predetermined wavelength to passing therethrough and gain entry into the image sensing element matrix 102. For example, in one embodiment, the inorganic optical layer 108 may serve as an ambient light sensor (ALS) mask used to allow visible light that has a wavelength substantially ranging from 780 nm to 390 nm to passing therethrough and gain entry into the image sensing element matrix 102. In another embodiment, the inorganic optical layer 108 may otherwise serve as a band pass filter used to allow infrared light that has a wavelength substantially greater than 850 nm passing therethrough and entering into the image sensing element matrix 102.

In the present embodiment, the inorganic optical layer 108 has a thickness substantially ranging from 3 μm to 6 μm, by which incident-light having wavelength substantially ranging from 780 nm to 390 nm can pass therethrough and entering into the image sensing element matrix 102.

However, it should be noted that, since the color filter layer 104, the micro-lenses 106 or some other optical films, such as black matrix (not shown), which are formed prior to the forming of inorganic optical layer 108 may be vulnerable to heat, thus the operating temperature of the thermal evaporation process for forming the inorganic optical layer 108 should not be greater than a heat deformation temperature of these optical films. For example, the operating temperature of the thermal evaporation process should be controlled less than the heat deformation temperature of the color filter layer 104. In some embodiments of the present invention, the operating temperature of the thermal evaporation process substantially ranges from 50° C. to 250° C. In the present embodiment, the thermal evaporation process has an operating temperature of 120° C.

In some embodiments of the present invention, the inorganic optical layer of the image sensor comprises at least two adjacent edges for forming an angle more than 90 degree (90°). For example, FIG. 1 illustrates a plan view of the image sensor 100 shown in accordance with FIG. 1E. In the present embodiment, the inorganic optical layer 108 is a polygonal film covering the active region 110, wherein the inorganic optical layer 108 has eight obtuse angles 109 formed by eight pairs of adjacent edges (e.g the adjacent edges 108a and 108b) of the inorganic optical layer 108.

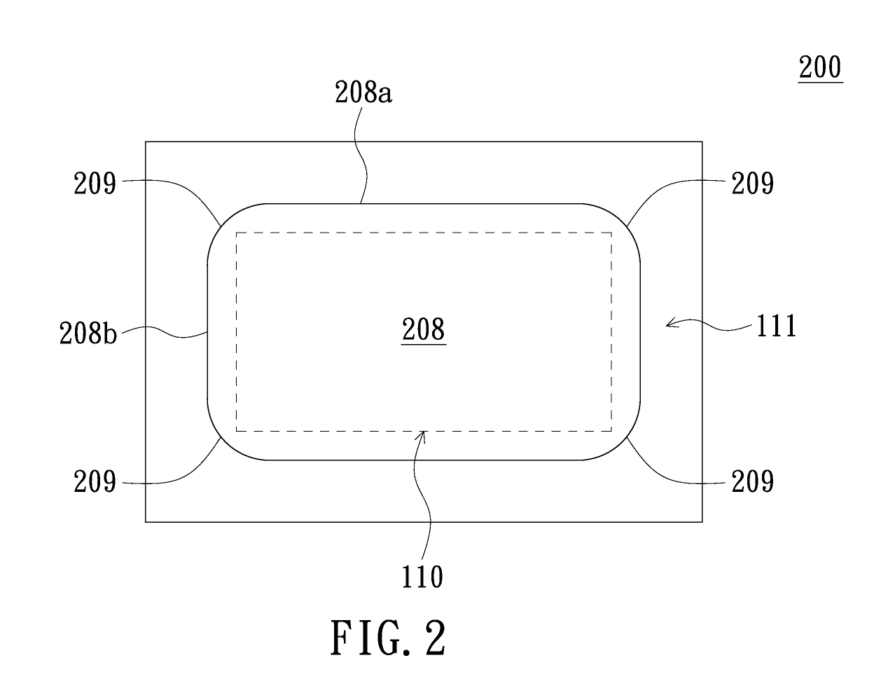

FIG. 2 illustrates a plan view of an image sensor 200 in accordance with another embodiment of the present invention. In the present embodiment, the structure of the image sensor 200 is similar to that of the image sensor 100, except that the inorganic optical layer 208 is a rectangular film covering the active region 110. In the present embodiment, the inorganic optical layer 208 has four rounded corners 209 formed by the four pairs of adjacent edges (e.g the adjacent edges 208a and 208b) of the inorganic optical layer 208.

Since adopting the obtuse angle 109 or the rounded corner 209 formed by these adjacent edges of the inorganic optical layer 108 or 208 may help the inorganic optical layer 108 (or 208) to evenly distributing the mechanical or thermal stress, thus this approach may prevent the dielectric layers and the optical films underneath the inorganic optical layer 108 or 208 from being cracked by thermal and mechanical stress resulted form the subsequent downstream processes for further integrating with other devices. Accordingly the yields of the image sensor 100 or the image sensor 200 and its application devices can be significantly improved.

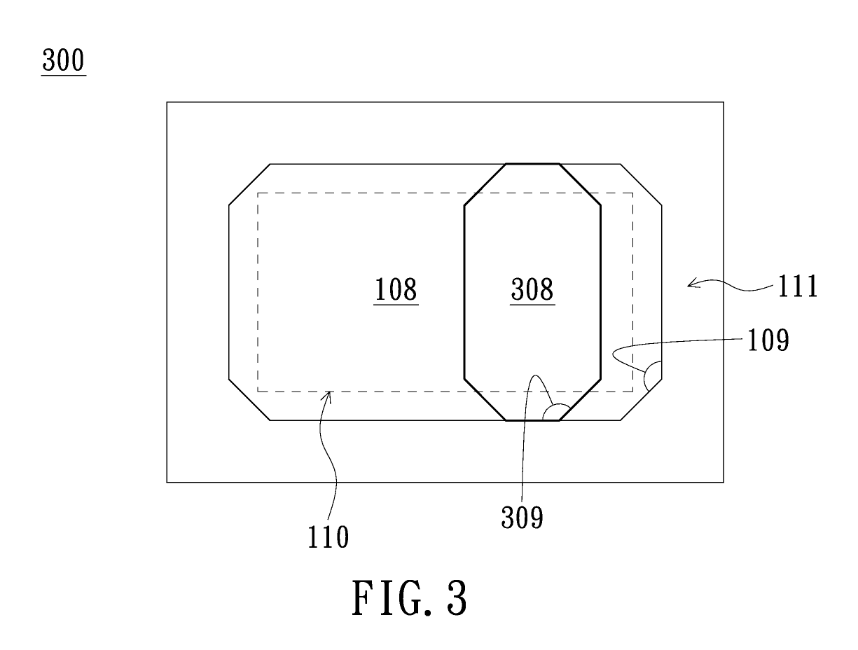

In some embodiment of the present invention, the image sensor may further comprise some other inorganic optical layers formed over the active region 110 or the peripheral region 111. For example, FIG. 3 is a plan view illustrating the image sensor 300, in accordance with one embodiment of the present invention. In the present embodiment, the image sensor 300, in comparison with the image sensor 100 depicted in FIG. 1, may further comprise an inorganic optical layer 308 partially overlapped with the inorganic optical layer 108. The inorganic optical layer 308, likewise to the inorganic optical layer 108, has eight obtuse angles 309 formed by eight pairs of adjacent edges of the inorganic optical layer 308 and allows light having predetermined wavelength passing therethrough. In some embodiments of the present invention, the inorganic optical layer 308 may serve as a color filter to restrain or filter out some of the incident-light from entering into the inorganic optical layer 108.

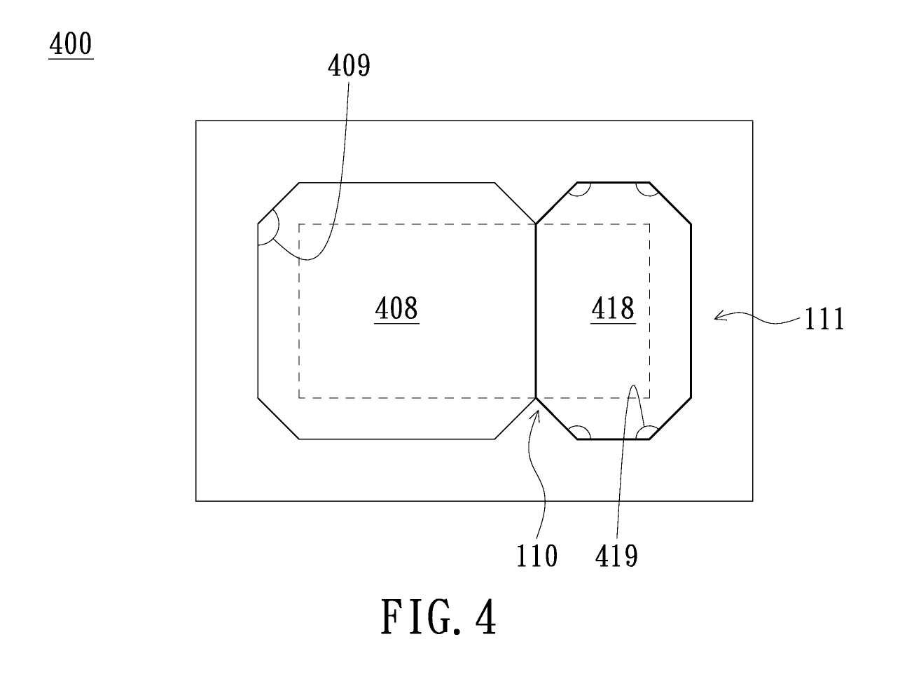

Alternatively, FIG. 4 illustrates a plan view of an image sensor 400 in accordance with one embodiment of the present invention. Similar to the image sensor 300, the image sensor 400 has two inorganic optical layers 408 and 418, and each of which has eight obtuse angles 409 or 419 respectively formed by eight pairs of adjacent edges of the correspondent inorganic optical layers 408 or 418. However, the inorganic optical layer 408 is disposed adjacent to the inorganic optical layer 418, instead of being overlapping with the inorganic optical layer 418.

In the present embodiment, the inorganic optical layer 408 covers a portion of the active region 110, and the inorganic optical layer 418 covers the other portion of the active region 110. Wherein, the inorganic optical layer 408 may serve as an ALS mask used to allow visible light passing therethrough and entering into one portion of the image sensing element matrix 102, and the inorganic optical layer 408 may serve as a band pass filter used to allow infrared light passing therethrough and entering into the other portion of the image sensing element matrix 102.

Because the characteristics of the inorganic optical layer 308, 408 and 418 and the steps for forming the same are similar to that of the inorganic optical layer 108. Thus the detailed process for forming thereof will not be redundantly described herein. Any modifications and similar arrangements included within the spirit and scope of the present invention may be done by the persons of ordinary skill in the art.

In accordance with the aforementioned embodiments of the present invention, an image sensor having a novel inorganic optical layer is provided, wherein the inorganic optical layer covers a plurality of image sensing elements of the image sensor and comprises at least two adjacent edges for forming an angle greater than 90 degrees (90°). Since the obtuse angle or rounded corner formed by the two adjacent edges of the inorganic optical layer may help to release the tensile or compression stress imposed on the image sensor, thus thermal stress and mechanical stress and adverse effects of the like resulted from the process for fabrication the image sensor or the subsequent downstream processes for further integrating with other devices can be reduced. As a result, yield of the image sensor can be significantly improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. An image sensor, comprising:
a substrate, having an active region;
a plurality of image sensing elements, disposed in the active region; and
a first inorganic optical layer, covering the image sensing elements and having at least two adjacent edges for forming an angle greater than 90 degrees (90°).

2. The image sensor according to claim 1, wherein the first inorganic optical layer allows light with a wavelength substantially ranging from 780 nm to 390 nm passing therethrough.

3. The image sensor according to claim 1, wherein the first inorganic optical layer has a thickness substantially ranging from 3 μm to 6 μm.

4. The image sensor according to claim 2, further comprising a second inorganic optical layer, covering the image sensing elements and having at least two adjacent edges for forming an angle greater than 90 degrees (90°).

5. The image sensor according to claim 4, wherein the second inorganic optical layer allows light with a wavelength substantially greater than 850 nm passing therethrough.

6. The image sensor according to claim 4, wherein the first inorganic optical layer and the second inorganic optical layer are partially overlapped.

7. The image sensor according to claim 4, wherein the first inorganic optical layer is disposed adjacent to the second inorganic optical layer.

8. The image sensor according to claim 1, further comprising:
a color filter layer, disposed between the image sensing elements and the first inorganic optical layer; and
a plurality of micro-lenses disposed between the color filter layer and the first inorganic optical layer.

9. The image sensor according to claim 8, further comprising a planarizing layer disposed between the color filter layer and the first inorganic optical layer or disposed over the first inorganic optical layer.

10. The image sensor according to claim 1, wherein the first inorganic optical layer has at least one rounded corner.

11. The image sensor according to claim 1, further comprising:
a color filter layer, disposed over the first inorganic optical film;
a planarizing layer disposed over the color filter layer; and
a plurality of micro-lenses disposed over the planarizing layer.

12. A method for fabricating an image sensor comprising:
forming a plurality of image sensing elements in an active region of a substrate; and
forming a first inorganic optical layer covering the image sensing elements, wherein the first inorganic optical layer comprises at least two adjacent edges for forming an angle greater than 90 degrees (90°).

13. The method for fabricating the image sensor according to claim 12, further comprising steps of forming a second inorganic optical layer covering the image sensing element matrix, wherein the second inorganic optical layer comprises at least two adjacent edges for forming an angle greater than 90 degrees (90°).

14. The method for fabricating the image sensor according to claim 12, wherein the first inorganic optical layer and the second inorganic optical layer are partially overlapped.

15. The method for fabricating the image sensor according to claim 12, wherein the second inorganic optical layer is formed adjacent to the first inorganic optical layer.

16. The method for fabricating the image sensor according to claim 12, wherein the first inorganic optical layer is deposited on the image sensing elements by an evaporation process.

17. The method for fabricating the image sensor according to claim 16, wherein the evaporation process has an operating temperature substantially less than a heat deformation temperature of a color filter layer.

18. The method for fabricating the image sensor according to claim 16, wherein the evaporation process has an operating temperature substantially ranging form 50° C. to 250° C.

19. The method for fabricating the image sensor according to claim 12, before the step of forming the first inorganic optical layer, further comprising:
forming a color filter layer on the image sensing elements; and
forming a plurality of micro-lenses disposed on the color filter layer.

20. The method for fabricating the image sensor according to claim 19, further comprising steps of forming a planarizing layer between the color filter layer and the first inorganic optical layer or over the first inorganic optical layer.
